(19) United States
(12) Patent Application Publication
(10) Pub. No.: US 2013/0306363 A1
(43) Pub. Date: Nov. 21, 2013

(54) STRUCTURE

(71) Applicant: CANON KABUSHIKI KAISHA, Tokyo (JP)

(72) Inventor: Koji Yukimasa, Yokohama-shi (JP)

(73) Assignee: CANON KABUSHIKI KAISHA, Tokyo (JP)

(21) Appl. No.: 13/868,586

(22) Filed: Apr. 23, 2013

(30) Foreign Application Priority Data
May 17, 2012 (JP) 2012-113758

(51) Int. Cl. H05K 9/00

(52) U.S. Cl. CPC H05K 9/00
USPC 174/376

(57) ABSTRACT

A structure comprises a plurality of signal conductors, a plurality of conductive conductors respectively conducting to the signal conductors, and capacitive members or capacitive characteristics between the plurality of signal conductors. The plurality of conductive conductors respectively include contact portions configured to come into contact with another conductor. The plurality of contact portions come into contact with the other conductor to form an EBG structure comprising the plurality of signal conductors having capacitive characteristics which prevent propagation of an electromagnetic wave in a specific frequency band, the plurality of conductive conductors having inductive characteristics, and a conductor ground plate, thereby shielding against an electromagnetic wave propagating in the other conductor.

### BACKGROUND OF THE INVENTION

1. Field of the Invention

The present invention relates to an EBG (Electromagnetic Band Gap) structure which prevents the propagation of electromagnetic waves in a specific frequency band.

2. Description of the Related Art

Recently, studies have been made on an EBG technique of preventing the propagation of electromagnetic waves in a specific frequency band. As an EBG structure, there is known a structure in which patch conductors are arranged at predetermined gap intervals in an array pattern within the same plane, and conductive vias extending from the patch conductors are connected to a ground conductor parallel to the patch conductors (for example, Japanese Patent Laid-Open No. 2002-510886). Japanese Patent Laid-Open No. 2010-16554 has proposed a structure in which edge portions facing cells adjacent to patch conductors are extended in the direction of a ground conductor to increase the electrostatic capacitance components of the adjacent cells.

When using a structure which prevents the propagation of electromagnetic waves by using an EBG structure, it is necessary to form an EBG structure as an integral structure using a printed board, metal members, and the like between an electromagnetic wave source and a region which prevents the propagation of electromagnetic waves. If, therefore, unintended electromagnetic waves are generated in an unexpected region in a printed board circuit, metal housing, or the like, it is necessary to redesign the printed board and the overall metal housing in order to prevent electromagnetic wave propagation.

When additionally mounting the members of a conventional EBG structure formed from a printed board and the like on a printed board, metal housing, or the like in which unintended electromagnetic waves have been generated, the ground conductor surface on which the EBG structure is mounted is disposed in contact with the metal surface of the printed board or metal housing. For this reason, it is necessary to bond the ground conductor of the EBG structure to the housing metal surface by providing an adhesion layer between them. Since the ground of the EBG structure is branched into two grounds to the ground conductor and the housing metal, it is not possible to obtain the effect of preventing the propagation of electromagnetic waves in a desired frequency band.

### SUMMARY OF THE INVENTION

The present invention provides a structure which can obtain the effect of preventing the propagation of electromagnetic waves in a desired frequency band with a simple arrangement.

A structure according to the present invention has the following arrangement. That is, a structure for shielding against an electromagnetic wave, the structure comprises: a signal conductor; a conductive conductor conducting to the signal conductor; and a dielectric member on which the plurality of signal conductors and the plurality of conductive conductors are arranged, wherein the conductive conductor includes a contact portion which is configured to come into contact with another conductor in which electromagnetic wave propagation occurs, and the contact portion comes into contact with the other conductor to suppress propagation of an electromagnetic wave in a specific frequency band.

The present invention can provide a structure which can obtain the effect of preventing the propagation of electromagnetic waves in a desired frequency band with a simple arrangement.

Further features of the present invention will become apparent from the following description of exemplary embodiments (with reference to the attached drawings).

### BRIEF DESCRIPTION OF THE DRAWINGS

FIG. 1 is a view showing an EBG structure according to the first embodiment;

FIG. 2 is a view showing a conventional EBG arrangement;

FIG. 3 is an equivalent circuit diagram of the EBG arrangement in FIG. 2;

FIG. 4 is an equivalent circuit diagram of an EBG structure in FIG. 1;

FIG. 5 is a view showing an example of the use of the EBG structure in FIG. 1;

FIG. 6 is a view showing an EBG structure according to the second embodiment;

FIG. 7 is a view showing a conventional EBG arrangement;

FIG. 8 is a view showing an example of the use of an EBG structure in FIG. 6;

FIG. 9 is a view showing an example of the use of an EBG structure according to the third embodiment between antennas;

FIG. 10 is a view showing an example of the use of an EBG structure according to the fourth embodiment to a circuit board;

FIG. 11A is a view showing an example of the use of an EBG structure according to the fifth embodiment to a wireless communication circuit board;

FIG. 11B is a view showing an example of the use of the EBG structure according to the fifth embodiment to a wireless communication circuit board; and

FIG. 11C is a view showing an example of the use of the EBG structure according to the fifth embodiment to a wireless communication circuit board.

### DESCRIPTION OF THE EMBODIMENTS

The embodiments of the present invention will be described in detail below with reference to the accompanying drawings.

### First Embodiment

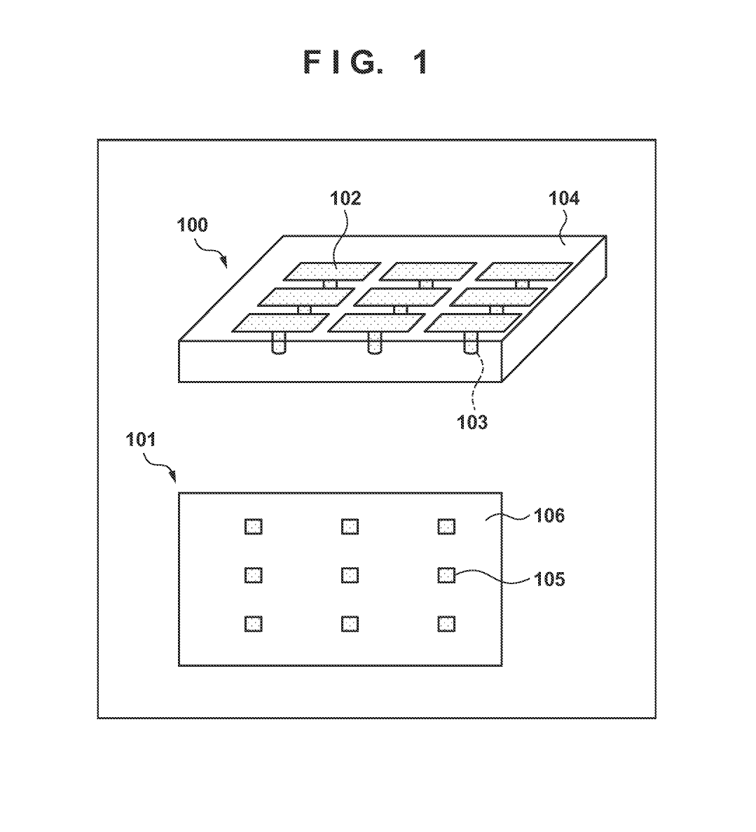

FIG. 1 is a view showing a perspective view 100 and rear view 101 of an EBG board according to the first embodiment.

An EBG board as a structure includes patch conductors 102 as signal conductors, conductive vias 103 as conductive conductors conducting to the patch conductors 102, and a dielectric member 104 as a capacitive member or a dielectric base material having a capacitive characteristic. As shown in FIG. 1, there are a plurality of patch conductors 102, for each of which the conductive via 103 is formed. In this case, the conductive via 103 is formed almost perpendicular to the signal conductor surface of the patch conductor 102 as a signal conductor.

Although the arrangement shown in FIG. 1 includes the dielectric member 104, the dielectric member 104 may be replaced with air. Each conductive via 103 is connected to the patch conductor 102, extends to the rear surface side through the dielectric member 104, and has a metal-exposed contact portion 105 which can come into contact with a metal portion of a mounted portion as a conductor. The contact portion 105 in FIG. 1 may not be rectangular but may be circular or polygonal. The dielectric member 104 may be disposed on the rear surface of the EBG board in an exposed state or an adhesion portion 106 may be provided on the contact surface of the rear surface so as to allow another conductor to be easily mounted.

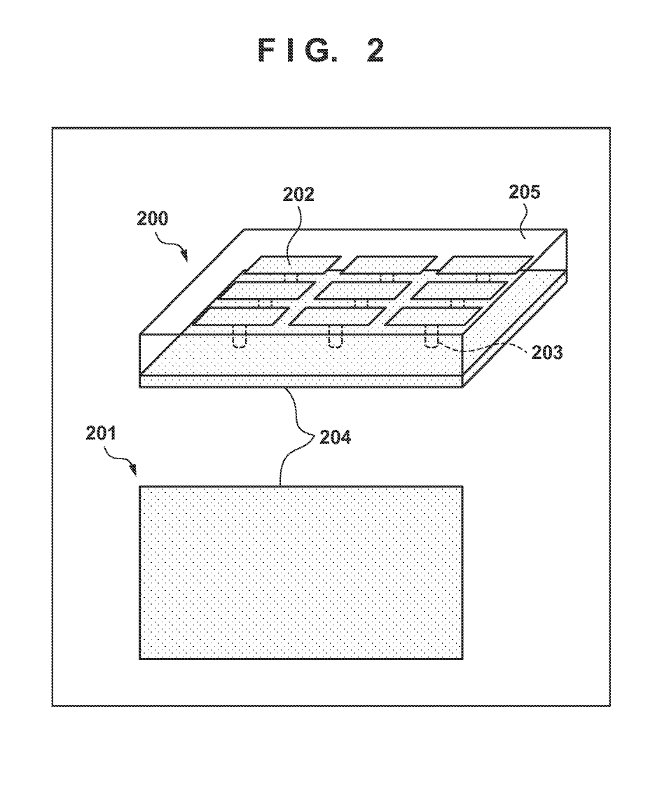

FIG. 2 is a view showing a perspective view 200 and rear view 201 of a general EBG structure.

A general EBG structure includes patch conductors 202, conductive vias 203, a ground conductor 204 on the rear surface, and a dielectric member 205. The dielectric member 205 may be replaced with air. The conductive vias 203 extend through the dielectric member 205 and are configured to electrically connect the patch conductors 202 to the ground conductor 204 on the rear surface.

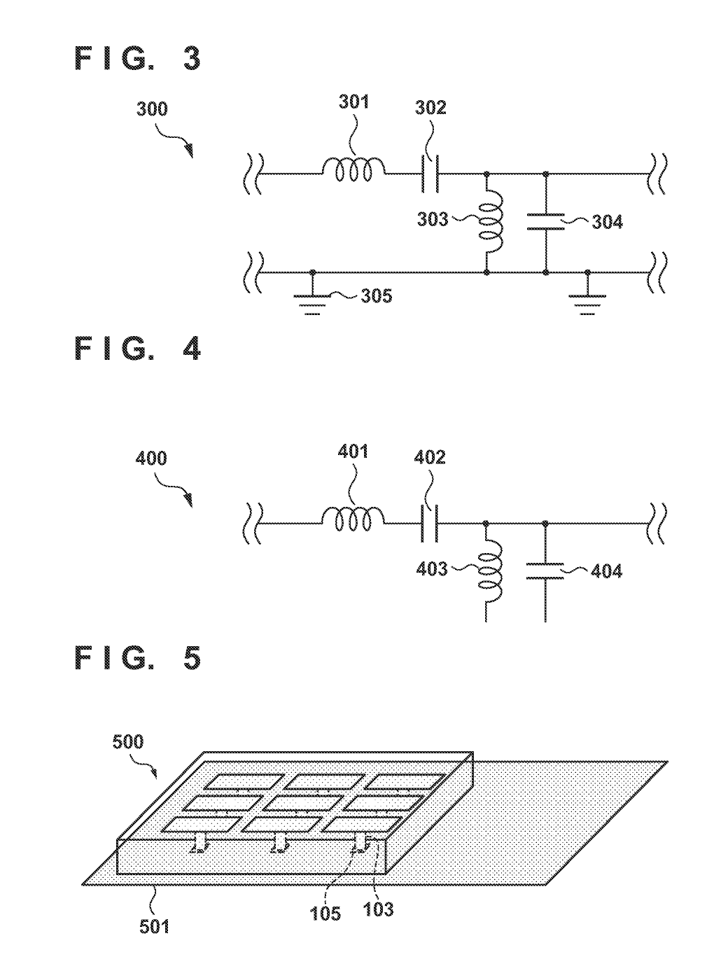

An equivalent circuit of the unit cell in FIG. 2 can be expressed by an equivalent circuit 300 of FIG. 3. FIG. 2 shows cells arrayed two-dimensionally. For this reason, an equivalent circuit should be two-dimensional. For the sake of simplicity, however, this circuit is expressed one-dimensionally in FIG. 3.

In the equivalent circuit 300, a series inducible reactance 301 indicates a length parallel to the ground conductor 204 of the patch conductors 202, and a series capacitive reactance 302 indicates the gap between the adjacent patch conductors 202. A parallel inducible reactance 303 indicates the conductive via 203 which electrically connects the patch conductor 202 to the ground conductor 204, and a capacitive reactance 304 connected in parallel between a signal line and a ground 305 indicates the gap between the patch conductor 202 and the ground conductor 204. The ground 305 in the equivalent circuit 300 indicates the ground conductor 204.

The frequency band between the resonance frequency of a series element and the resonance frequency of a parallel element is a band (EBG: Electromagnetic Band Gap) in which the phase constant is 0 and through which no electromagnetic waves are transmitted. Parameters are designed to adjust the series resonance frequency and the parallel resonance frequency so as to obtain a desired (specific) frequency band. An EBG structure 200 shown in FIG. 2 is configured to shield against electromagnetic waves in the desired frequency band by designing parameters such an adjacent patch interval, via diameter, and via length.

FIG. 4 is a view showing an equivalent circuit 400 of a unit cell in this embodiment in FIG. 1.

Since the correspondence between the circuit elements and the structure in FIG. 2 is the same as that in FIG. 3, a description of it will be omitted. The equivalent circuit 400 is expressed by a series inducible reactance 401, a series capacitive reactance 402, a parallel inducible reactance 403, and a parallel capacitive reactance 404. This circuit includes no element corresponding to the ground 305 in FIG. 3. In this embodiment, a mounted metal portion is brought into contact with the conductive vias 103 on the rear surface to design an original EBG structure, that is, an equivalent circuit of a unit cell as shown in FIG. 3.

FIG. 5 is a view showing an example of the use of a structure 500 according to the first embodiment in FIG. 1.

The contact portions 105 of the conductive vias 103 of the first embodiment are brought into contact with a metal conductor 501 to be mounted. Bringing the metal conductor 501 into contact with the contact portions 105 of the conductive vias 103 will make the mounted metal conductor 501 function as ground. As a consequence, in this example of the use of this embodiment, an equivalent circuit diagram of a unit cell becomes the same as FIG. 3, thereby obtaining the original electromagnetic wave shielding effect. That is, when unintended electromagnetic waves propagate to the metal conductor 501, bringing the structure of the first embodiment into contact with the metal conductor 501 can prevent the propagation of electromagnetic waves and shield against them.

The following is an effective application of the first embodiment. Assume that unintended electromagnetic wave propagation has occurred on a conductor ground plate (an electronic circuit board, metal housing, or the like) at the stage of design and development of an electronic device. In this case, the structure of the embodiment is added afterward to a portion where it is desired to suppress electromagnetic wave propagation. This makes it possible to suppress unintended electromagnetic wave propagation. Using the structure of the embodiment can obtain desired characteristics as the system without redesigning an electronic circuit board or metal housing.

The first embodiment has exemplified a general EBG structure. However, the present invention is not limited to this, and can be applied to another type of EBG structure including via portions which can come into contact with a ground portion in the EBG structure.

Forming the arrangement of the first embodiment by using a thin board such as a flexible board allows application to the bent portions or curved surface portions of a housing. If a bonding surface is small, a board can be easily cut and bonded.

### Second Embodiment

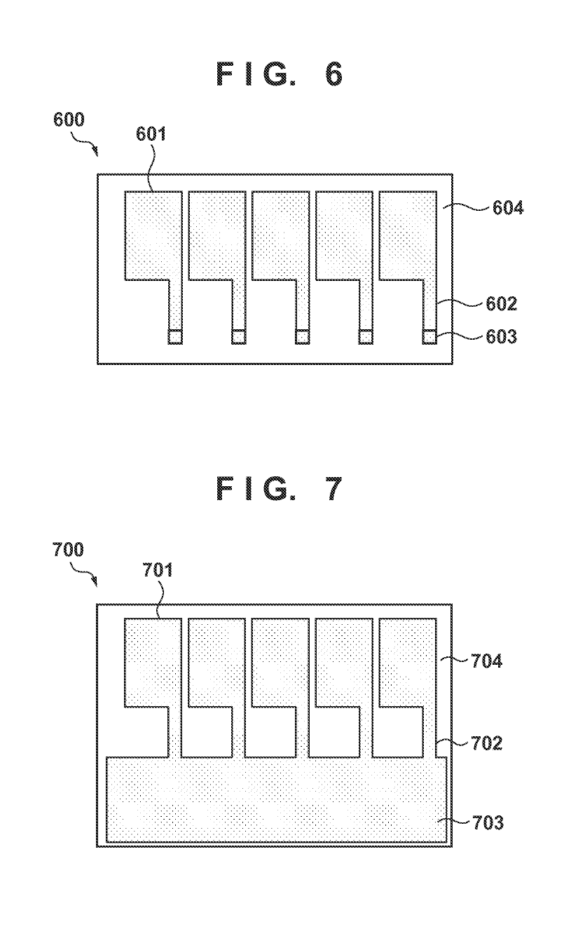

FIG. 6 is a view showing an EBG arrangement 600 according to the second embodiment.

FIG. 6 shows the surface of an example of an arrangement obtained by implementing the same functional arrangement as that in the first embodiment on a board pattern, which is mounted by using only a pattern on the surface layer of a circuit board. This arrangement includes patch conductors 601, conductive conductors 602, contact portions 603 which comes into contact with a mounted metal portion, and a dielectric portion 604, which are arranged within the same plane. The contact portion 603 has a metal-exposed surface on the distal end of the conductive conductor. FIG. 6 shows the contact portions 603 each having the same width of a rectangle as that of the conductive conductor 602. However, each contact portion may neither have the same width as that of the conductive conductor 602 nor have a rectangular shape. Although the second embodiment has exemplified the dielectric portion 604 as a board, it may be a thin sheet material which is not a board material such as paper, cellophane, wood piece, or cloth. In addition, an adhesion portion may be provided on the lower portion (the mounting surface for another conductor) of the dielectric portion 604 so as to allow another conductor to be easily mounted. In this case, the dielectric portion 604 as a dielectric board is configured in contact with the patch conductors 601 and the conductive conductors 602 so as to be almost parallel to their planes.

FIG. 7 is a view showing a surface of an example of an EBG arrangement 700 of a surface layer pattern.

The arrangement in FIG. 7 includes patch conductors 701, conductive conductors 702, a ground conductor 703, and a dielectric portion 704. As in the first embodiment, the conductive conductors 702 electrically connect the patch conductor 701 to the ground conductor 703. The equivalent circuit of FIG. 7 is the same as that of FIG. 3. The series inducible reactance 301 indicates a length parallel to the ground conductor 703 of the patch conductors 701, and a series capacitive reactance 302 indicates the gap between the adjacent patch conductors 701. The parallel inducible reactance 303 indicates the conductive conductor 702, and the capacitive reactance 304 indicates the gap between the patch conductor 701 and the ground conductor 703. The ground 305 of the equivalent circuit 300 indicates the ground conductor 703.

Design parameters for an EBG structure include the size and shape of the patch conductor 701, the gap between the patch conductors 701, the interval between the patch conductor 701 and the ground conductor 703, the size and shape of the conductive conductor 702, and the like. The series resonance frequency and the parallel resonance frequency are changed by changing these parameters. It is possible to obtain a desired electromagnetic wave cutoff band by changing parameters.

The equivalent circuit of the EBG structure according to the second embodiment shown in FIG. 6 becomes the same as that shown in FIG. 4 as in the first embodiment. The equivalent circuit 400 without the ground 305 is equivalent to that shown in FIG. 3, and is the same as that except for the ground 305. For this reason, a description of the correspondence relationship between the respective circuit elements (reactances) and the structure will be omitted.

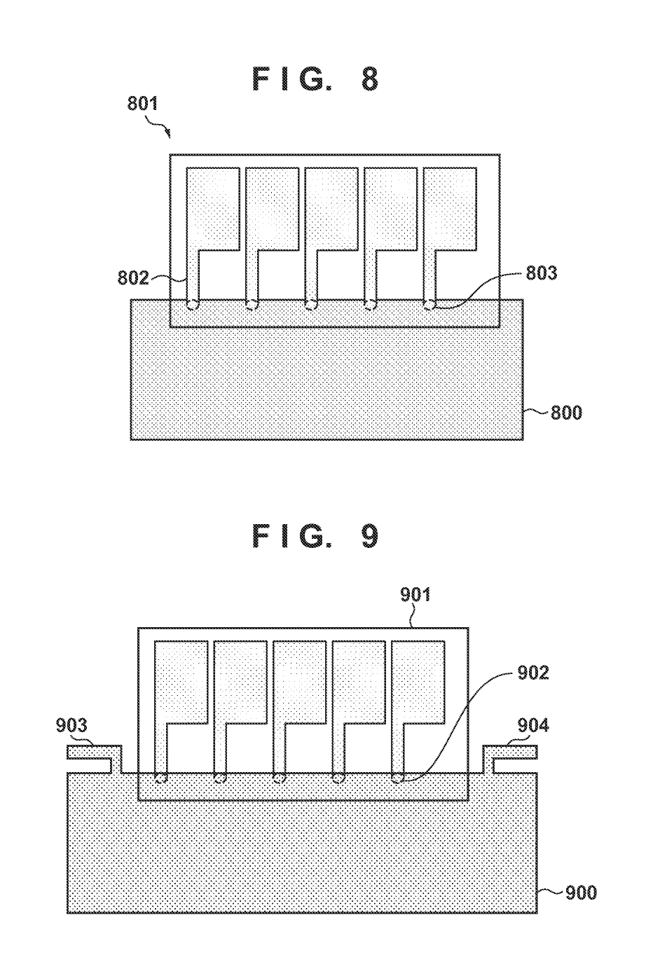

FIG. 8 is a view showing an example of the use of the second embodiment.

An EBG structure 801 of the second embodiment is bonded to a metal conductor 800 (to be mounted) by using an adhesion portion. The contact surfaces (the rear surfaces in FIG. 6) of metal-exposed contact portions 803 at the distal ends of conductive conductors 802 are brought into contact with the metal conductor 800. As described above, the contact portions 803 and the adhesion portion are formed within the same plane. Bringing the conductive conductors 802 into contact with the metal conductor 800 will make the metal conductor 800 function as ground. This makes the equivalent circuit 400 function as the equivalent circuit 300, thereby exhibiting the electromagnetic wave shielding effect as that of an original EBG structure.

The present invention can be applied to an arrangement in which conductive conductors can be brought into contact with a mounted metal member by using an EBG structure having a board pattern other than that in the second embodiment.

Forming the arrangement of the second embodiment by using a thin board such as a flexible board can apply the arrangement to the bent portions or curved surface portions of the housing. If a bonding surface is small, a board can be easily cut and bonded.

### Third Embodiment

FIG. 9 is a view showing an example of the application of an EBG structure according to the third embodiment to a communication circuit board. A communication circuit board 900 is a circuit board on which an antenna 903 (antenna 1) and an antenna 904 (antenna 2) are mounted. An EBG structure 901 of this embodiment includes metal-exposed contact portions 902 of the EBG structure.

Although the EBG structure 901 may be of a multilayer type as in the first embodiment or a surface layer type as in the second embodiment, this embodiment will exemplify the surface layer type of the second embodiment.

The antennas 903 and 904 use the ground common to the communication circuit board 900 and operate in the same frequency band. The distance between the antennas is equal to or less than ¼ the operating frequency band. For this reason, the mutual coupling between the antennas degrades the characteristics of each antenna as a unit antenna. The contact portions 902 of this embodiment are bonded to the ground portion between the antennas of the communication circuit board 900. Since the ground of the communication circuit board 900 functions as the ground of the EBG structure 901, the EBG structure 901 functions as an original EBG structure. This can block a surface current in the ground between the antennas and shorten the distance between the antennas without degrading the characteristics between the antennas.

This embodiment has exemplified the application of the EBG structure between the two antennas to a communication apparatus. However, the embodiment can also be applied to the arrangement between two or more antennas. Although the antennas in FIG. 9 are inverted L-shaped antennas, the arrangement of each antenna is not limited to this.

### Fourth Embodiment

FIG. 10 is a view showing an example of the application of an EBG structure according to the fourth embodiment to a circuit board. Reference numeral 1001 denotes a circuit board; 1002, a signal generation unit; and 1003, an EBG structure. The EBG structure 1003 may be either of the multilayer type as in the first embodiment or of the surface layer type as in the second embodiment.

Metal-exposed contact portions are bonded on the circuit board 1001 at positions outside the signal generation unit 1002 so as to be in contact with the ground of the circuit board 1001. Since the ground of the circuit board 1001 functions as the ground of the EBG structure 1003, it is possible to obtain the original electromagnetic wave shielding effect and block unintended power supply noise from the signal generation unit 1002 to the outside.

### Fifth Embodiment

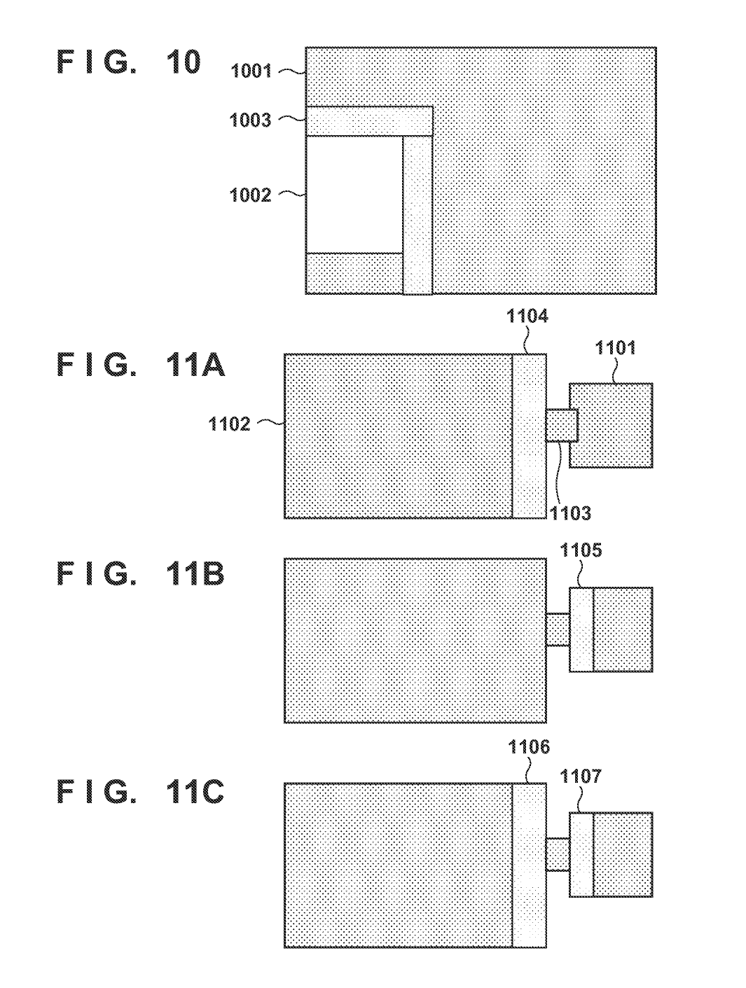

FIGS. 11A, 11B, and 11C are views each showing an example of the application of an EBG structure according to the fifth embodiment to a wireless communication circuit. Reference numeral 1101 denotes a wireless communication circuit board; 1102, a main board; 1103, a connection cable; and 1104 to 1107, EBG structures. The EBG structures 1104 to 1107 may be either of the multilayer type as in the first embodiment or of the surface layer type as in the second embodiment. In this embodiment, the wireless communication circuit board 1101 and the main board 1102 are formed from different boards. The wireless communication circuit board 1101 is connected to the main board 1102 via the connection cable 1103. The main board 1102 controls the wireless communication circuit board 1101 via the connection cable 1103.

Referring to FIG. 11A, the metal-exposed contact portion of the EBG structure 1104 is bonded to the ground of the main board 1102 so as to be in contact with it.

Referring to FIG. 11B, the metal-exposed contact portion of the EBG structure 1105 is bonded to the ground of the wireless communication circuit board 1101 so as to be in contact with it.

Referring to FIG. 11C, the metal-exposed contact portions of the EBG structures 1106 and 1107 are bonded to the ground of the main board 1102 and the ground of the wireless communication circuit board 1101 so as to be in contact with them.

The ground of the main board 1102 functions as the grounds of the EBG structures 1104 and 1106. The ground of the wireless communication circuit board 1101 functions as the grounds of the EBG structures 1105 and 1107. For this reason, the EBG structures 1104 to 1107 each exhibit the original electromagnetic wave shielding effect. This can shield against surface currents between the wireless communication circuit board 1101 and the main board 1102 in the electromagnetic wave cutoff band of each of the EBG structures 1104 to 1107.

In addition, bonding each of the EBG structures 1104 to 1107, which has an electromagnetic wave cutoff region at frequencies to be cut off, to the wireless communication circuit board 1101 or the main board 1102 makes it possible to suppress the influence of noise on it.

In addition, bonding the EBG structures 1106 and 1107 to the wireless communication circuit board 1101 to shield against noise from the wireless communication circuit board 1101 in the manner shown in FIG. 11C can further suppress noise from the wireless communication circuit board 1101. Bonding the EBG structures 1106 and 1107 for shielding against noise from the wireless communication circuit board 1101 and main board 1102 to the boards can suppress the flow of noise from one board to the other board. It is also possible to obtain the same effect by bonding each of the the EBG structures 1106 and 1107 for shielding against noise from the wireless communication circuit board 1101 and the main board 1102 to the other board.

The present invention is directed to the EBC structure and allows achievement of the electromagnetic wave shielding effect by using the mounted metal as the EBG ground.

The present invention is an EBG structure which can shield against electromagnetic waves in an EBG by using a metal member to be mounted as an EBG ground.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application 2012-113758, filed on May 17, 2012 which is hereby incorporated by reference herein in its entirety.

What is claimed is:

1. A structure for shielding against an electromagnetic wave, the structure comprising:
a signal conductor;
a conductive conductor conducting to said signal conductor; and
a dielectric member on which said plurality of signal conductors and said plurality of conductive conductors are arranged,
wherein said conductive conductor includes a contact portion which is configured to come into contact with another conductor in which electromagnetic wave propagation occurs, and
said contact portion comes into contact with the other conductor to suppress propagation of an electromagnetic wave in a specific frequency band.

2. The structure according to claim 1, wherein the other conductor comprises an electronic circuit board.

3. The structure according to claim 1, wherein the other conductor comprises a metal housing.

4. The structure according to claim 1, wherein the other conductor comprises a communication circuit board.

5. The structure according to claim 1, wherein the other conductor comprises a communication circuit board on which a plurality of antennas are arranged.

6. The structure according to claim 1, wherein said conductive conductor is configured to be almost perpendicular to a signal conductor surface of said signal conductor.

7. The structure according to claim 1, wherein said signal conductor and said conductive conductor are configured within the same plane.

8. A structure comprising a plurality of signal conductors, a plurality of conductive conductors respectively conducting to said signal conductors, and capacitive members or capacitive characteristics between said plurality of signal conductors, wherein
said plurality of conductive conductors respectively include contact portions configured to come into contact with another conductor, and
said plurality of contact portions come into contact with the other conductor to form an EBG structure comprising said plurality of signal conductors having capacitive characteristics which prevent propagation of an electromagnetic wave in a specific frequency band, said plurality of conductive conductors having inductive characteristics, and a conductor ground plate, thereby shielding against an electromagnetic wave propagating in the other conductor.

9. The structure according to claim 8, wherein said conductive conductor is configured to be almost perpendicular to a signal conductor surface of said signal conductor.

10. The structure according to claim 8, further comprising a dielectric base material between said signal conductor and said contact portion.

11. The structure according to claim 8, wherein said conductive conductor comprises a via.

12. The structure according to claim 8, wherein said signal conductor and said conductive conductor are configured within the same plane.

13. The structure according to claim 12, further comprising a dielectric board which contacts with said signal conductor and said conductive conductor so as to be almost parallel to planes of said signal conductor and said conductive conductor.

14. The structure according to claim 8, further comprising an adhesion portion for mounting the other conductor.

15. The structure according to claim 8, wherein said contact portion and said adhesion portion in the structure are configured within the same plane.
